(19) United States
(12) Patent Application Publication
(10) Pub. No.: US 2007/0164276 A1
(43) Pub. Date: Jul. 19, 2007

(54) Method for Forming Memory Layers

(75) Inventors: Reimund Engl, Regensburg (DE); Jorg Schumann, Dresden (DE); Andreas Walter, Dresden (DE); Recai Sezi, Roettenbach (DE); Anna Maltenberger, Leutenbach (DE)

Correspondence Address: EDELL, SHAPIRO & FINNAN, LLC, 1901 RESEARCH BLVD., SUITE 400, ROCKVILLE, MD, 20850, US

(73) Assignee: Qimonda AG, Munchen (DE)

(21) Appl. No.: 11/621,756

(22) Filed: Jan. 10, 2007

Related U.S. Application Data
(63) Continuation of application No. PCT/EP05/53144, filed on Jul. 1, 2005.

(30) Foreign Application Priority Data
Jul. 30, 2004 (DE) 102004037151.2

(51) Int. Cl. H01L 51/00; H01L 51/40

(52) U.S. Cl. 257/40; 438/82; 438/99; 438/60; 257/431

(57) ABSTRACT

Layers are produced, where the layers include a first layer formed of a metal and a second layer formed of an organic compound, the metal and the organic compound entering into an interaction, so that the layer serves as an electroactive layer for nonvolatile memories, the metal layer being deposited onto a substrate and, if appropriate, patterned, then being coated with an organic compound and being treated with a second organic compound.

### CROSS REFERENCE TO RELATED APPLICATIONS

This application is a continuation of International Application No. PCT/EP2005/053144, filed on Jul. 1, 2005, entitled “Method for Forming Memory Layers,” which claims priority under 35 U.S.C. §119 to Application No. DE 102004037151.2 filed on Jul. 30, 2004, entitled “Method for Forming Memory Layers,” the entire contents of which are hereby incorporated by reference.

### FIELD OF THE INVENTION

The invention relates to the field of non-volatile memory cells, and in particular to a method for producing such cells.

### BACKGROUND

It is known from the prior art that complexes between a metal and a further organic compound may serve as a basis for the nonvolatile memory cells having two states of different electrical resistance. One example is e.g. the cell in accordance with U.S. Pat. No. 4,371,883, which discloses a memory cell based on copper with TCNQ. In this case, copper and TCNQ form a charge transfer complex layer, referred to hereinafter as a charge transfer layer or CT layer.

A further cell based on metal with an organic compound is also described in DE 103 55 561.7. In order to produce such a cell, the active material is brought between two suitable electrodes. By way of example, a copper-coated wafer may be used as a substrate for this purpose. An insulating dielectric, for example silicon dioxide or a polymer, is situated between silicon and copper.

After the patterning of the copper, e.g. in the form of thin lines, the substrate is treated with a solution of the electron acceptor. In this case, a layer of the reaction product (for example CuTCNQ) formed from copper and the acceptor forms on the copper surface. The dielectric does not react with the acceptor. Afterward, the top electrode is applied and patterned, e.g., in the form of lines which form an angle of 90° with lower copper lines. So-called cross-point cells arise at the crossover points of the upper and lower tracks, the dimensions of the cells being defined by the respective track widths. In this case, copper forms the bottom electrode, it being possible for the top electrode to be formed from different materials, such as aluminum, titanium, tantalum, tantalum nitride, titanium nitride, etc.

The patterning of the electrodes may be effected by perforated masks, such as e.g. by vapor deposition of the electrode material, printing techniques or photolithography. The lateral cell geometry may be arbitrary and is not restricted to the cross-point arrangement mentioned above.

The formation of a charge transfer or CT complex between copper and the acceptor solution takes place relatively rapidly. During this reaction, however, it is difficult on the one hand to regulate the layer thickness of the reaction product in a targeted manner, so that the thin layers that are significantly thinner than 1 μm are very difficult to produce. On the other hand, it is possible for domains having different morphologies to arise during this reaction, which, inter alia, may also have different electrical properties, for example switching voltage.

As an alternative, a CT complex can be produced by vapor-depositing the acceptor onto the substrate in a vacuum chamber, it also being possible to produce thin layers by means of this method. In order to form the reaction product, however, a subsequent thermal treatment is necessary in this case, e.g. on a hot plate or in a furnace. The unreacted acceptor is subsequently removed by means of a solvent. In this case, too, the acceptor reacts only with the metal, but not with the dielectric, so that the excess acceptor can be flushed away from the dielectric. The disadvantage of this method is that rough layers arise in this case, which may have a surface roughness of more than 50 nm. Moreover, the method requires a very precise temperature regulation on the entire contact area of the hot plate with the substrate, since local temperature fluctuations cause different reaction rates, which can lead to inhomogeneity in the layer.

### SUMMARY

A method is provided which makes it possible to produce CT layers comprising a layer made of a metal and a second layer made of an organic compound, and which gives rise to a uniform and homogeneous layer having the least possible surface roughness. The method further produces layers with thicknesses of less than 100 nm.

A method for producing charge transfer or CT layers which can be used in nonvolatile memories includes depositing a metal layer onto a substrate and, if appropriate, patterning the metal layer. The metal layer is coated with a first organic compound, and the coated metal layer thus obtained is treated with the vapor of a second organic compound. The first organic compound and the metal layer interact to form an electroactive layer between the metal and the organic compound, where the electroactive layer can be used for the nonvolatile memories forms between the metal and the organic compound.

The above and still further features and advantages will become apparent upon consideration of the following detailed description of specific embodiments thereof.

### DETAILED DESCRIPTION

As noted above, a method for producing CT layers which can be used in nonvolatile memories includes depositing a metal layer onto a substrate and, if appropriate, patterning the metal layer. The metal layer is coated with a first organic compound, and the coated metal layer thus obtained is treated with the vapor of a second organic compound. The first organic compound and the metal layer interact to form an electroactive layer between the metal and the organic compound, where the electroactive layer can be used for the nonvolatile memories forms between the metal and the organic compound.

The substrate on which the metal layer is deposited may be silicon, germanium, gallium arsenide, gallium nitride, a polymer, ceramic glass or metal. The substrate may be, moreover, any desired material which contains any desired compound of silicon, germanium or gallium. The substrate may also be a material that has already been processed and may contain one to a plurality of layers of contacts, interconnects, insulating layers and further microelectronic components.

In one embodiment, the substrate is silicon that has already been processed according to front end of line (FEOL), that is to say already contains electrical components such as transistors, capacitors, etc. Situated between the substrate and the metal layer there is preferably an insulating layer, particularly when the substrate is electrically conductive. However, there may also be a plurality of arbitrary layers between the substrate and the metal layer.

The substrate may serve as a carrier material or, alternatively, the substrate may also fulfill an electrical function (e.g., evaluation, control, etc.). For the last-mentioned case there are electrical contacts between the substrate and the electrodes which are applied to the substrate. The electrical contacts are, for example, contact holes filled with an electrical conductor (vias).

In another embodiment, the metal is copper. The metal layer may also be part of an electrode, which may also have a plurality of layers, at least one layer comprising copper. The further layers may be made of, e.g., titanium, titanium nitride, tantalum, tantalum nitride, tungsten, tantalum-tungsten, tungsten nitride, tungsten carbonitride, iridium oxide, ruthenium oxide, strontium ruthenium oxide, or any desired combination of the materials. Moreover, there may also be further layers made of, e.g., silicon, titanium nitride silicon, silicon oxynitride, silicon oxide, silicon carbide, silicon nitride or silicon carbonitride.

The metal layer may be in any desired form, such as, e.g., a plate, a film, which may be a metal layer applied to a substrate by vacuum techniques or electrolytic deposition. A thin film of a metal which has been applied on the abovementioned substrate is preferred. This may be achieved, e.g., by vapor deposition, sputtering, CVD, electrochemical metallization or printing techniques. The metal may also be patterned, for which lithography, printing methods or vapor deposition through a perforated mask are suitable.

The first organic compound, which coats the metal layer, is preferably selected from the group consisting of: 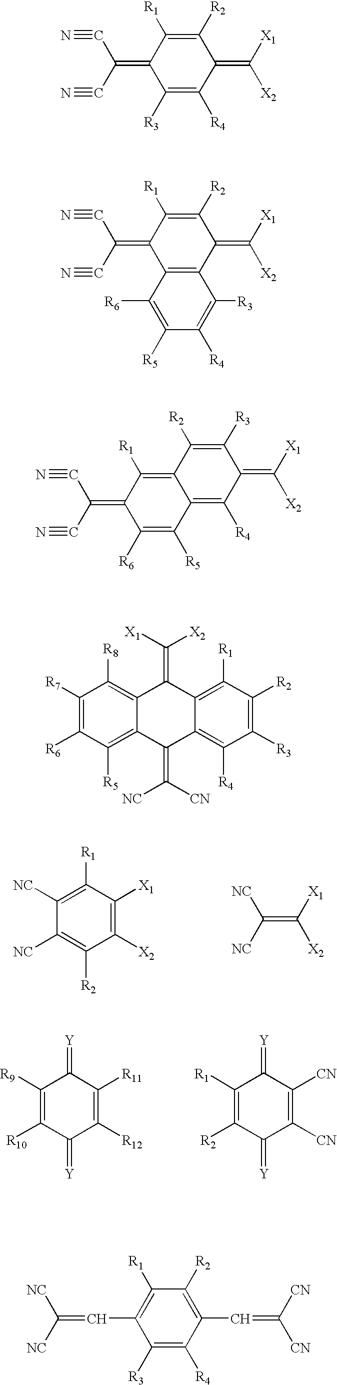 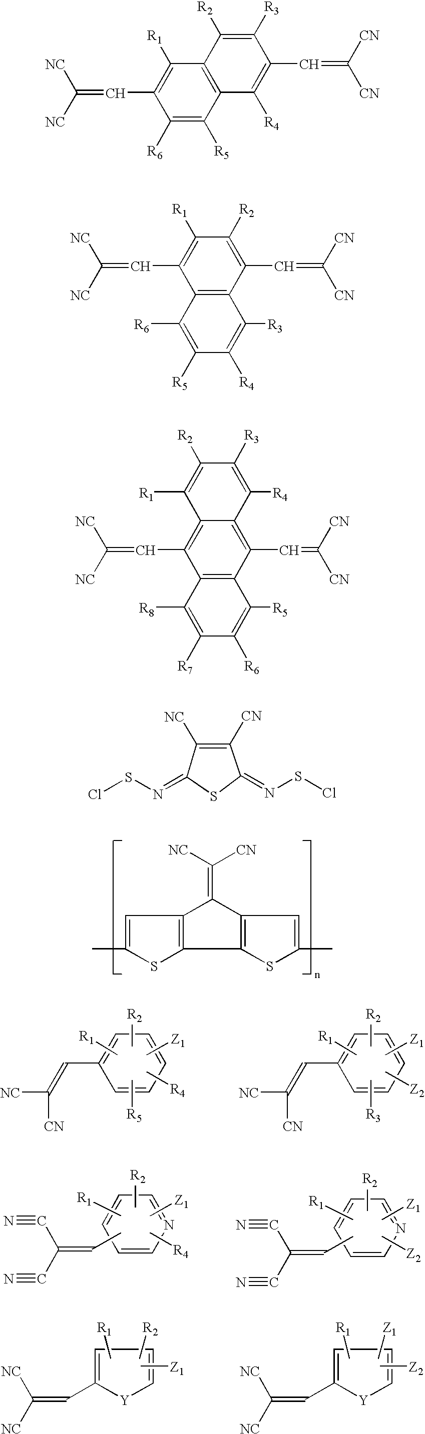
where each of R₁, R₂, R₃, R₄, R₅, R₆, R₇ and R, independently of one another, may be one of: H, F, Cl, Br, I (iodine), alkyl, alkenyl, alkynyl, O-alkyl, O-alkenyl, O-alkynyl, S-alkyl, S-alkenyl, S-alkynyl, OH, SH, aryl, heteroaryl, O-aryl, S-aryl, NH-aryl, O-heteroaryl, S-heteroaryl, CN, NO₂, —(CF₂)ₙ—CF₃, —CF((CF₂)ₙCF₃)₂, —Q—(CF₂)ₙ—CF₃, —CF(CF₃)₂, and —C(CF₃)₃, or one of the following: 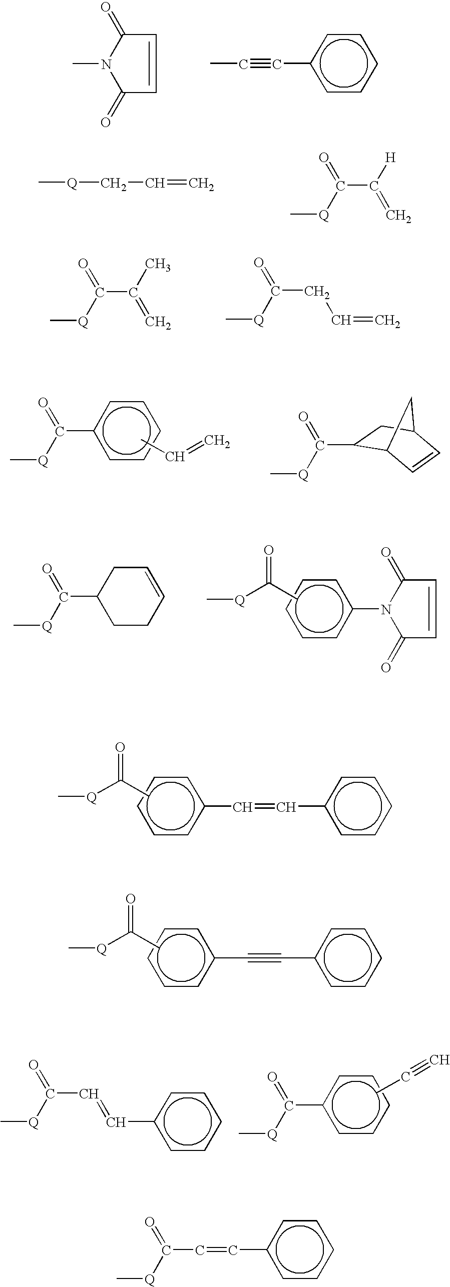
where n=0 to 10;
Q is one of: —O— and —S—;
each of R₉, R₁₀, R₁₁, R₁₂, independently of one another, is one of:
F, Cl, Br, I, CN, and NO₂;
each of R₁₃, R₁₄, R₁₅, R₁₆, R₁₇, independently of one another, is one of: H, F, Cl, Br, I, CN, NO₂;
each of X₁ and X₂, independently of one another, is one of: 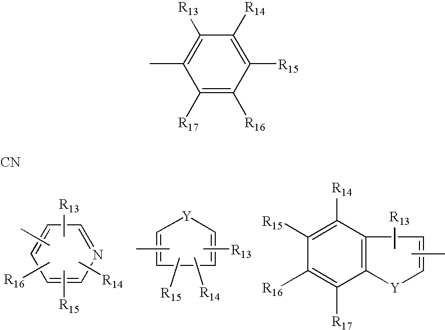
Y is one of: O, S, and Se;
and each of Z₁ and Z₂, independently of one another, is one of CN and NO₂.

In a preferred embodiment, the organic compound is TCNQ.

The coating of the metal layer with the first organic compound may be achieved in a vacuum chamber, with pressure and temperature being regulated. The precise conditions are described, e.g., in DE 103 55 561.7. The vapor deposition is preferably achieved under inert gas, such as noble gases or nitrogen, it also being possible to add other gases, such as, e.g., oxygen, as required. The substrate holder can be heated or cooled. Preferred temperatures for the substrate holder are within the range of −20° C. to 100° C., the temperature range between 20° C. and 40° C. being particularly preferred.

After the metal layer has been coated with the first organic compound, the substrate enters a second temperature-regulated chamber which is saturated or has been saturated with the vapor of the second organic compound. This treatment predominantly enables the reaction between the metal and the acceptor. The constant vapor temperature and vapor concentration surprisingly enable a very uniform reaction. The pressure at which the treatment is achieved is within the range of 300 torr to 2000 torr. The treatment time is preferably between 30 seconds and 15 minutes. The temperature-regulated chamber may be integrated into a vacuum installation. In addition, however, glass apparatuses, e.g. reactors or desiccators may also serve as a chamber.

In one preferred embodiment, the second organic compound is an organic solvent or a mixture of different solvents. A solvent having a nitrile group is particularly preferred. Acetonitrile is particularly preferred either as a single treatment reagent or in a solvent mixture with further organic solvents.

The method provides a number of advantages, including the advantage that the layer thickness is precisely controlled, that the layer is inherently homogeneous, and that the surface roughness of the layer is very low.

One particular advantage of the method is that, in applications where the first organic compound has a lower vaporization or sublimation temperature than the temperature at which the reaction between the metal layer and the organic compound takes place, the interaction between the metal layer and the organic compound cannot be brought about on a hot plate or in a furnace. There are also organic compounds which decompose at the temperature at which the reaction between the metal layer and the first organic compound takes place. The method makes it possible, however, also to cause these first organic compounds to react with the metal layer in order to produce a layer serving as an electroactive layer for the nonvolatile memories.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed:

1. A method for producing charge transfer layers comprising a first layer formed of a metal and a second layer formed of a first organic compound, wherein the metal and the first organic compound form a charge transfer complex that serves as an electroactive layer in a nonvolatile memory, the method comprising:
depositing a metal layer onto a substrate;
coating the metal layer with the first organic compound; and
treating the metal layer coated with the first organic compound with a vapor comprising a second organic compound.

2. The method of claim 1, wherein the substrate comprises one of silicon, germanium, gallium arsenide, gallium nitride, a polymer, ceramic glass and metal.

3. The method of claim 1, wherein the metal layer comprises copper.

4. The method of claim 1, wherein the deposition of the metal layer is achieved by one of vapor deposition, sputtering, CVD, electrochemical metallization and printing techniques.

5. The method of claim 1, wherein the metal layer is patterned by photolithography.

6. The method of claim 1, wherein the first organic compound is selected from the group consisting of: 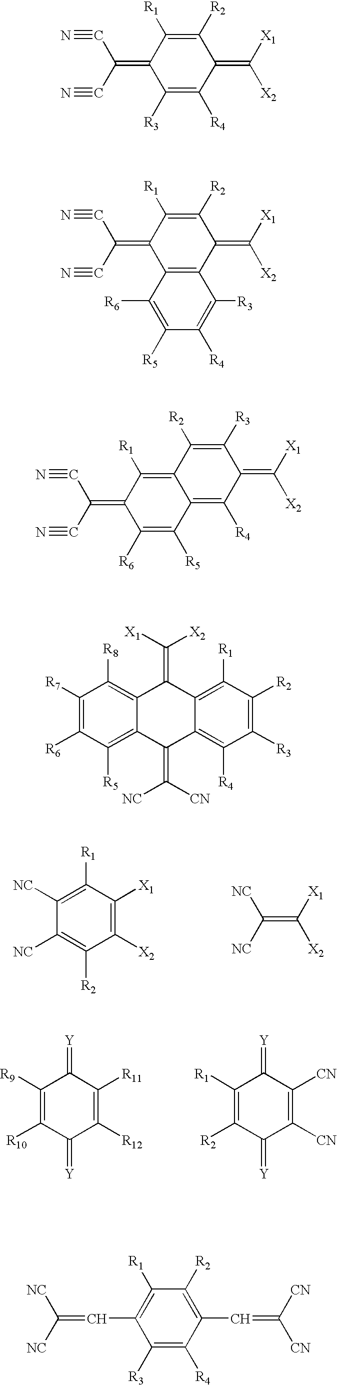 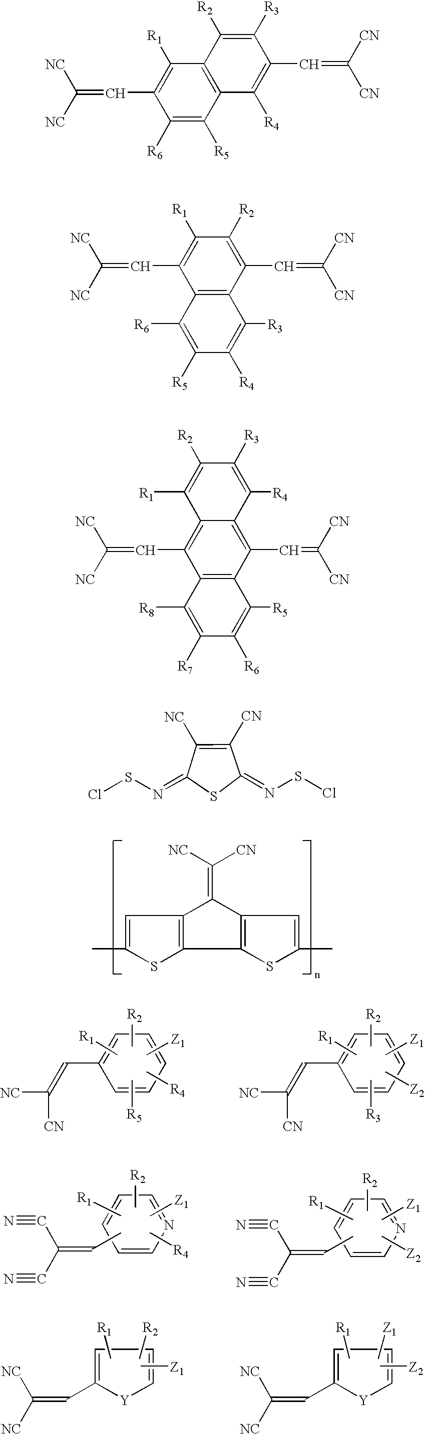
wherein:
each of R₁, R₂, R₃, R4, R₅, R₆, R₇ and R₈, independently of one another, is one of the following: H, F, Cl, Br, I, alkyl, alkenyl, alkynyl, O-alkyl, O-alkenyl, O-alkynyl, S-alkyl, S-alkenyl, S-alkynyl, OH, SH, aryl, heteroaryl, O-aryl, S-aryl, NH-aryl, O-heteroaryl, S-heteroaryl, CN, NO₂, —(CF₂), —CF₃, —CF((CF₂)ₙCF₃)₂, —Q—(CF₂)ₙ—CF₃, —CF(CF₃)₂, —C(CF₃)₃, 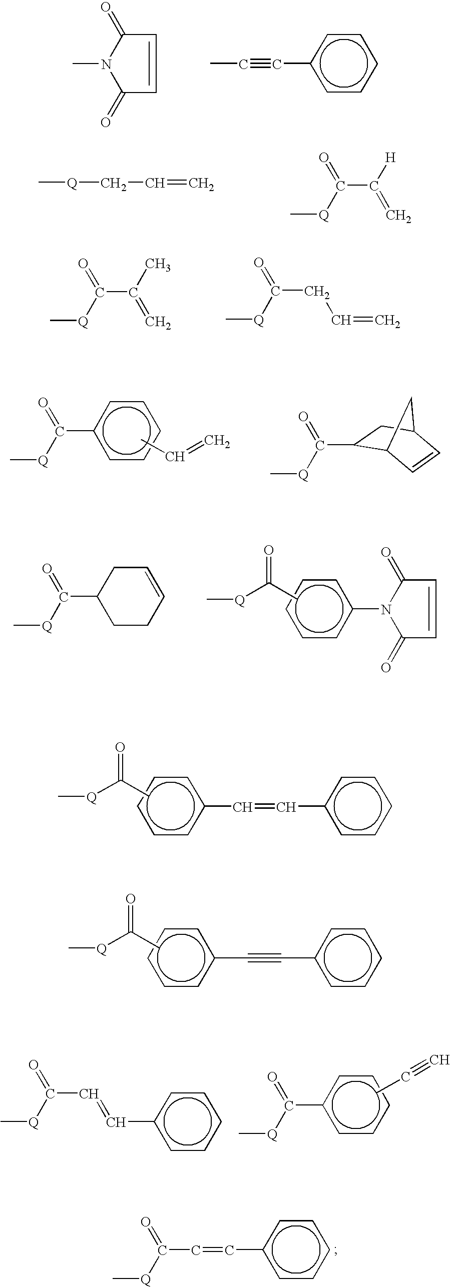
n=0 to 10;
Q is one of —O— and —S—;
each of R₉, R₁₀, R₁₁, R₁₂, independently of one another, is one of F, Cl, Br, I, CN, and NO₂;
each of X₁ and X₂, independently of one another, is one of: 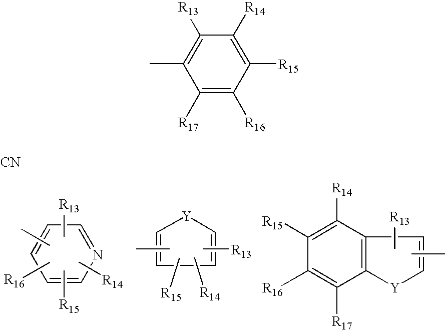
each of R₁₃, R₁₄, R₁₅, R₁₆, R₁₇, independently of one another, is one of H, F, Cl, Br, I, CN, and NO₂;
Y is one of O, S, and Se; and
each of Z1 and Z2, independently of one another is one of CN and NO₂.

7. The method of claim 1, wherein the coating of the metal layer with the organic compound is achieved by vapor deposition.

8. The method of claim 1, wherein the treatment with the second organic compound is achieved at a temperature within the range of 20° C. to 40° C.

9. The method of claim 1, wherein the treatment with the second organic compound is achieved at a pressure in the range of 300 torr to 2000 torr.

10. The method of claim 1, wherein the metal layer coated with the first organic compound is treated with the second organic compound for a period between 30 seconds and 15 minutes.

11. The method of claim 1, wherein the second organic compound comprises an organic solvent or a mixture of organic solvents.

12. The method of 11, wherein the organic solvent includes a nitrile group.

13. The method of claim 11, wherein the solvent comprises acetonitrile.

14. The method of 1, wherein the second organic compound comprises an organic solvent mixture including acetonitrile.

15. A method of producing charge transfer layers, the charge transfer layers comprising a first layer formed of a metal and a second layer formed of a first organic compound such that the metal and the first organic compound form a charge transfer complex, the charge transfer complex serving as an electroactive layer in a nonvolatile memory, the method comprising:
depositing a metal layer onto a substrate;
coating the metal layer with the first organic compound by vapor deposition of the organic compound onto the metal layer; and
treating the metal layer coated with the first organic compound with a vapor of a second organic compound comprising a solvent including a nitrile group.

16. A charge transfer layer formed on a substrate by depositing a metal layer on the substrate and coating the metal layer with a first organic compound by vapor deposition of the organic compound onto the metal layer, and then treating the metal layer coated with the first organic compound with a vapor comprising a second organic compound, wherein the second organic compound comprises a nitrile group.

17. The charge transfer layer of claim 16, wherein the first organic compound is selected from the group consisting of: 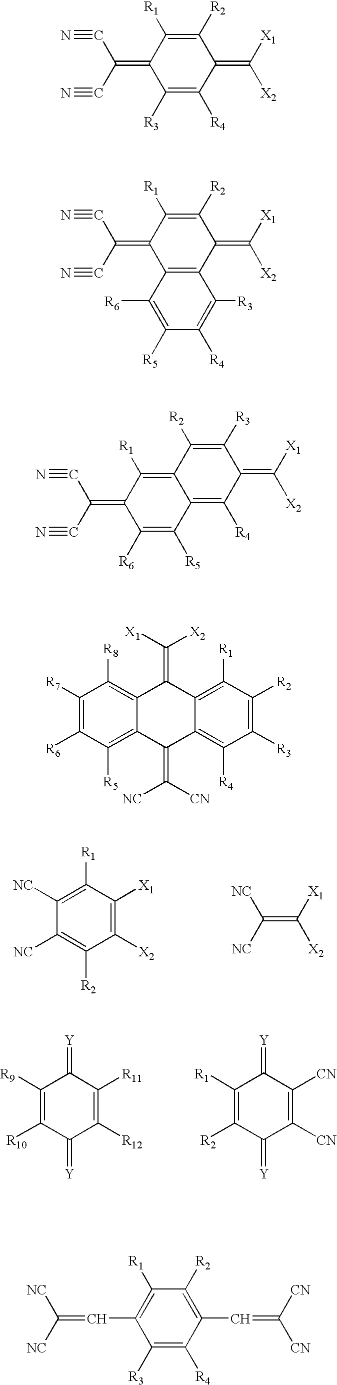 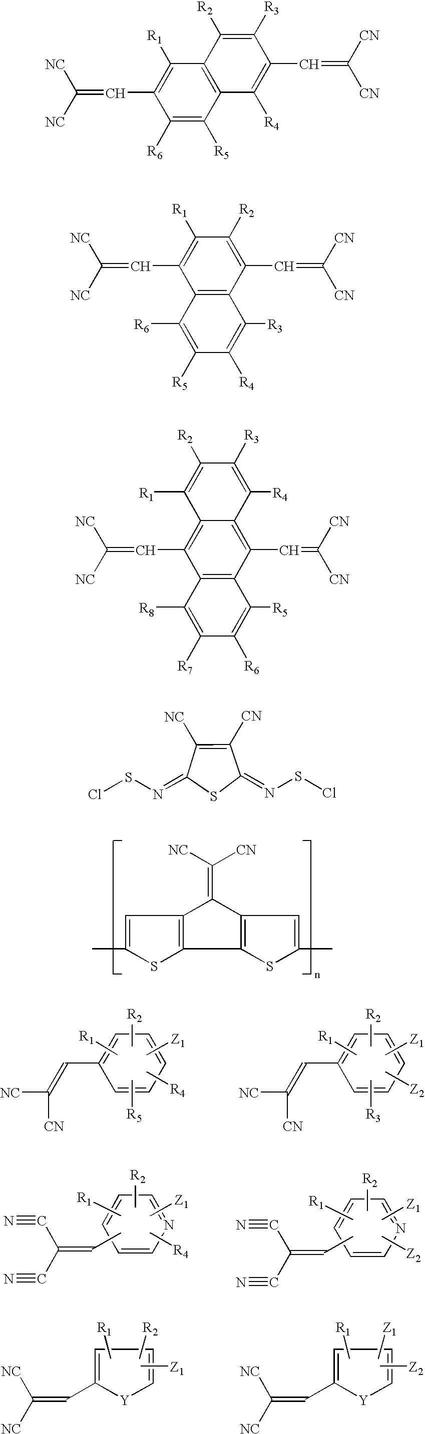
wherein:
each of R₁, R₂, R₃, R₄, R₅, R₆, R₇ and R₈, independently of one another, is one of the following: H, F, Cl, Br, I, alkyl, alkenyl, alkynyl, O-alkyl, O-alkenyl, O-alkynyl, S-alkyl, S-alkenyl, S-alkynyl, OH, SH, aryl, heteroaryl, O-aryl, S-aryl, NH-aryl, O-heteroaryl, S-heteroaryl, CN, NO₂, —(CF₂)ₙ—CF₃, —CF((CF₂)ₙCF₃)₂, —Q—(CF₂)ₙ—CF₃, —CF(CF₃)₂, —C(CF₃)₃, 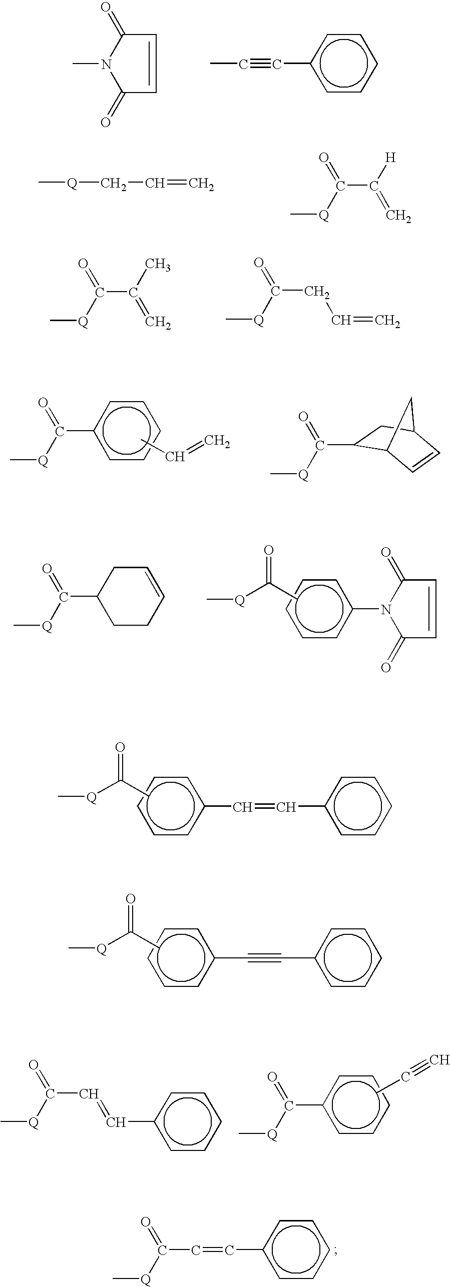
n=0 to 10;
Q is one of —O—and —S—;
each of R₉, R₁₀, R₁₁, R₁₂, independently of one another, is one of F, Cl, Br, I, CN, and NO₂;
each of X₁ and X₂, independently of one another, is one of: 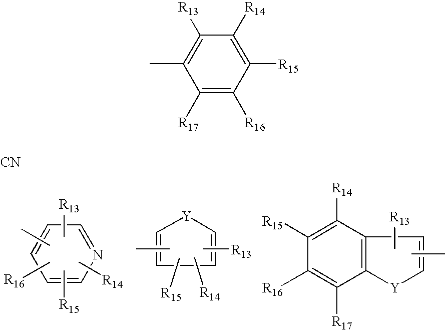
each of R₁₃, R₁₄, R₁₅, R₁₆, R₁₇, independently of one another, is one of H, F, Cl, Br, I, CN, and NO₂;
Y is one of O, S, and Se; and
each of Z1 and Z2, independently of one another is one of CN and NO₂.
